(19) United States
(12) Patent Application Publication
(10) Pub. No.: US 2022/0407474 A1
(43) Pub. Date: Dec. 22, 2022

(54) REGULATING OFF-STATE IMPEDANCE AND LEAKAGE CURRENT OF A POWER AMPLIFIER IN A TRANSCEIVER

(71) Applicant: Intel Corporation, Santa Clara, CA (US)

(72) Inventors: Jaeyoung CHOI, Portland, OR (US); Ali AZAM, Hillsboro, OR (US)

(21) Appl. No.: 17/351,283

(22) Filed: Jun. 18, 2021

(51) Int. Cl. H03F 1/52; H03F 3/24; H04B 1/38

(52) U.S. Cl. CPC H03F 1/523; H03F 3/245; H04B 1/38; H03F 2200/294; H03F 2200/451; H03F 2200/426

(57) ABSTRACT

A power amplifier may be configured to operate in an on state and an off state. The power amplifier may include a plurality of transistors and an impedance controller circuit. The plurality of transistors may be electrically coupled to an electrical ground and an output of the power amplifier. The impedance controller circuit may be electrically coupled to the plurality of transistors and a reference voltage. The impedance controller circuit may be configured to provide the reference voltage to the plurality of transistors when the power amplifier is in the off state to cause a leakage current to flow between the reference voltage and the electrical ground.

### TECHNICAL FIELD

The aspects discussed in the present disclosure are related to regulating off-state impedance and leakage current of a power amplifier in a transceiver.

### BACKGROUND

Unless otherwise indicated in the present disclosure, the materials described in the present disclosure are not prior art to the claims in the present application and are not admitted to be prior art by inclusion in this section.

A transceiver may operate in a receive state in which a low noise amplifier (LNA) receives multiple receive signals via an antenna. The transceiver may also operate in a transmit state in which a power amplifier (PA) generates transmit signals to be wirelessly transmitted by the antenna. The LNA and the PA may be designed as a shared matching network that does not include series switches. For example, the PA may include a stacked or cascode configuration of transistors to generate the transmit signals.

The subject matter claimed in the present disclosure is not limited to aspects that solve any disadvantages or that operate only in environments such as those described above. Rather, this background is only provided to illustrate one example technology area where some aspects described in the present disclosure may be practiced.

### BRIEF DESCRIPTION OF THE DRAWINGS

Example aspects will be described and explained with additional specificity and detail through the use of the accompanying drawings in which:

FIG. 1 illustrates a block diagram of an example transceiver system that includes a PA, an LNA, and an antenna;

FIG. 2 illustrates an example of the PA that may be implemented in the transceiver system of FIG. 1. electrically coupled to a load;

FIG. 3 illustrates another example of the PA that may be implemented in the transceiver system of FIG. 1. electrically coupled to the load;

FIG. 4 illustrates yet another exemplary PA that may be implemented in the transceiver system of FIG. 1. electrically coupled to the load; and

FIG. 5 illustrates a graphical representation of simulations using a circuit design of the PA of FIG. 2,

all according to at least one aspect described in the present disclosure.

### DETAILED DESCRIPTION

The following detailed description refers to the accompanying drawings that show, by way of illustration, exemplary details in which aspects of the present disclosure may be practiced.

The word “exemplary” is used herein to mean “serving as an example, instance, or illustration”. Any aspect or design described herein as “exemplary” is not necessarily to be construed as preferred or advantageous over other aspects or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPoint™, among others, or any combination thereof. Registers, shift registers, processor registers, data buffers, among others, are also embraced herein by the term memory. The term “software” refers to any type of executable instruction, including firmware.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

A transceiver may operate in a receive state in which a receiver (e.g., an LNA) receives multiple receive signals via an antenna. The transceiver may also operate in a transmit state in which a transmitter (e.g., a PA) generates transmit signals to be wirelessly transmitted by the antenna. The receiver and the transmitter may be designed as a shared matching network that does not include series transistors (e.g., switches). In addition, the transmitter may include multiple PAs that operate at different times when the transceiver is in the transmit state.

The PA may include a stacked configuration or cascode configuration of the transistors (e.g., an upper stack and a lower stack). The upper stack may be electrically coupled to an output of the PA and the lower stack. The lower stack may be electrically coupled between the upper stack and an electrical ground.

In the receive state, the LNA may receive the receive signals and noise from the PA. The noise may be due to parasitic conductance (e.g., thermal noise, noise due to leakage current, or some combination thereof), an off-impedance level, or some combination thereof of the PA. The noise may degrade operation of the LNA. In addition, in the transmit state, an operating PA within the transmitter may receive the noise from a non-operating PA. The noise may degrade operation of the operating PA.

The parasitic conductance of the PA may occur due to sizing of the transistors, operational parameters of the PA or the transistors, or some combination thereof. For example, a power level of a power supply for the PA may be greater than the power level of the power supply to the other components within the transceiver (e.g., the LNA).

The transistors in the PA may be large enough to push and sink sufficient current to cause the antenna to transmit a wireless signal in a radio frequency (RF). However, a length of gates of the transistors may be relatively short for their size to increase bandwidth or efficiency of the PA or to reduce a footprint of the PA compared to transistors that include long gate lengths. The large transistors, in the off state, may generate greater leakage current, greater shunt conductance, or some combination thereof compared to small transistors. The large transistors with short gate lengths, in the off state, may generate even greater leakage current, even greater shunt conductance, or some combination thereof compared to small transistors.

An off-biasing voltage range of large transistors that include short gate lengths (e.g., a voltage range to achieve off state biasing) may be narrower than the off-biasing voltage range of large transistors that include long gate lengths. The off-biasing voltage range of the large transistors that include short gate lengths may be difficult to achieve in the off state, which may prevent the transistors from entering a deep shut off state. The deep shut off state may include when a difference between a gate voltage and a source voltage is smaller than a threshold voltage of the transistor (e.g., a minimum difference between the gate voltage and the source voltage to conduct current on the transistor). For example, the deep shut off state may include when the difference between the gate voltage and the source voltage is equal to a negative value (e.g., when a voltage level of the gate voltage is less than a voltage level of the source voltage). In addition, process variations during wafer production may further narrow or alter the off-biasing voltage range. The process variations may cause the off-biasing voltage range to vary between transistors, wafers, and PAs. In addition, a hot corner in the PA (e.g., a portion of the PA that operates in a hot environment or lower voltage threshold corner) may reduce or narrow the off-biasing voltage range even more. When the transistors of the upper stack fail to enter the deep shut off state, an off-impedance level of the PA may be reduced, which may contribute to the noise generated by the PA.

Some PAs include an impedance controller configured to reduce the impact of the noise. Some impedance controller technologies may include a tail switch electrically coupled between the lower stack and the electrical ground. The tail switch, when the PA is in the off state, may electrically isolate the lower stack from the electrical ground to prevent the leakage current from flowing between the power supply and the electrical ground (e.g., switch off a leakage path between the lower stack and the electrical ground). The tail switch may electrically isolate the lower stack from the electrical ground to prevent the leakage current from flowing to also increase the impedance of the upper stack. These impedance controller technologies may create a voltage drop within the PA due to a differential configuration of the PA. The voltage drop of the tail switch may reduce efficiency, gain, linearity, or some combination thereof of the PA. In addition, to reduce the voltage drop of the tail switch, the tail switch may be large, which may increase a footprint and parasitic conductance of the PA.

Some PAs may be designed to increase the threshold voltages of the transistors in the PA to reduce the noise. However, these PAs may include reduced performance. For example, these PAs may include a reduced gain, reduced speed, increased noise, or some combination thereof.

Impedance controller circuits described in the present disclosure may cause the upper stack to enter the deep shut off state while permitting the leakage current to flow between a reference voltage and the electrical ground to prevent the leakage current from flowing to the output of the amplifier. In addition, the impedance controller circuits described in the present disclosure may not impact performance of the PA in the on state by placing the impedance controller circuit in a position that does not introduce a voltage drop. Further, the impedance controller circuit described in the present disclosure may cause the upper stack to the enter the deep shut off state without altering the threshold voltages of the transistors.

The impedance controller circuits described in the present disclosure may be electrically coupled to the transistors and the reference voltage. For example, the impedance controller circuit may include a switch electrically coupled between the PA and the reference voltage. In the off state, the impedance controller circuit may provide the reference voltage to the transistors to cause the upper stack to transition to the deep shut off state. For example, the switch may transition to a closed state to provide the reference voltage to the transistors.

The impedance controller circuit may increase the off impedance of the upper stack, reduce the noise, or some combination thereof in the off state of the PA. In addition, the impedance controller circuit may cause the leakage current to flow between the reference voltage and the electrical ground rather than between the power supply and the electrical ground. Further, the impedance controller circuit may not degrade performance of the PA because the impedance controller circuit does not alter the upper stack or the lower stack (e.g., the impedance controller does not alter differential rails of the transistors). Likewise, the impedance controller circuit may reduce a fabrication cost or manufacturing cost of the PA compared to PAs that include the tail switch.

The impedance controller circuit causing the upper stack to enter the deep shut off state may also compensate for process variations that occur. For example, the voltage threshold of the upper stack may be inconsistent and the impedance controller circuit providing the reference voltage may increase the off impedance even more than standard operation.

These and other aspects of the present disclosure will be explained with reference to the accompanying figures. It is to be understood that the figures are diagrammatic and schematic representations of such example aspects, and are not limiting, nor are they necessarily drawn to scale. In the figures, features with like numbers indicate like structure and function unless described otherwise.

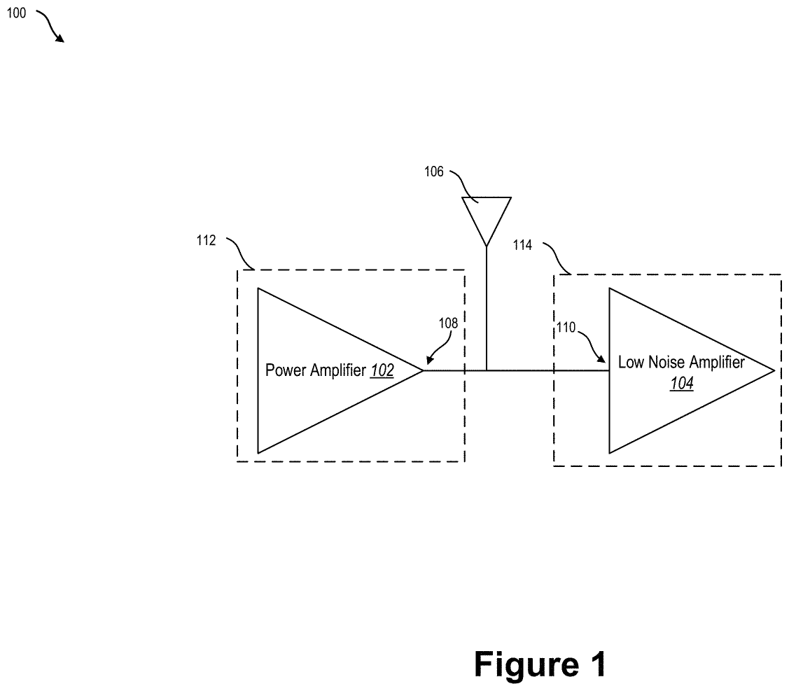

FIG. 1 illustrates a block diagram of an example transceiver system 100 that includes a PA 102, an LNA 104, and an antenna 106, in accordance with at least one aspect described in the present disclosure. The PA 102 may include an output 108 that is electrically coupled to the antenna 106 and an input 110 of the LNA 104. The input 110 of the LNA 104 may also be electrically coupled to the antenna 106. The PA 102 may form at least a portion of a transmitter 112 of the transceiver system 100. The transmitter 112 may include multiple PAs 102. The LNA 104 may form at least a portion of a receiver 114 of the transceiver system 100.

The transceiver system 100 may operate in a transmit state in which the transmitter 112 is in an on state and the receiver 114 is in an off state. In the transmit state, the transmitter 112 may generate transmit signals. The transmitter 112 may provide the transmit signals to the antenna 106 to be wirelessly transmitted to another electronic device. The transceiver system 100 may also operate in a receive state in which the receiver 114 is in the on state and the transmitter 112 is in an off state. In the receive state, the antenna 106 may receive one or more receive signals. The antenna 106 may provide the one or more receive signals to the receiver 114 for processing.

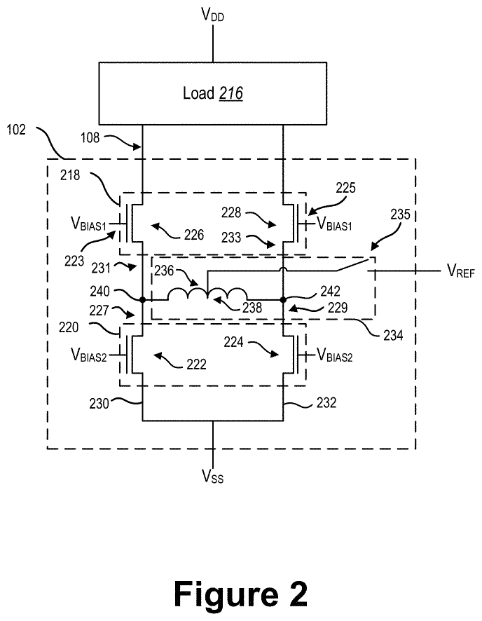

FIG. 2 illustrates an example of the PA 102 that may be implemented in the transceiver system 100 of FIG. 1. electrically coupled to a load 216, in accordance with at least one aspect described in the present disclosure. The PA 102 may include an upper stack 218 and a lower stack 220 that include multiple transistors. The lower stack 220 may include a first transistor 222 and a second transistor 224. The upper stack 218 may include a third transistor 226 and a fourth transistor 228. The first transistor 222 and the third transistor 226 may form a high rail 230. The second transistor 224 and the fourth transistor 228 may form a low rail 232. The first transistor 222 may include a gate 223 and a drain 227. The second transistor 224 may include a drain 229. The third transistor 226 may include a source 231. The fourth transistor 228 may include a gate 225 and a source 233.

The first transistor 222 and the second transistor 224 may be electrically coupled to an electrical ground (illustrated as V_{SS} in FIG. 1). The third transistor 226 and the fourth transistor 228 may be electrically coupled to the output 108 of the PA 102 and the load 216. The load 216 may represent the antenna 106, the LNA 104, a matching network of the PA 102 (not illustrated), or some combination thereof of FIG. 1. The gate 223 of the first transistor 226 and the gate 225 of the fourth transistor 228 may be electrically coupled to a first bias voltage (illustrated as V_{BIAS1} in FIG. 1). In addition, a gate of the first transistor 222 and a gate of the second transistor 224 may be electrically coupled to a second bias voltage (illustrated as V_{BIAS2} in FIG. 1).

The impedance controller circuit 234 may include an inductor 236 and a switch circuit 235. The inductor 236 may include a first node 240, a second node 242, and a center pin 238. The first node 240 may be electrically coupled to the drain 227 of the first transistor 222 and the source 231 of the third transistor 226. The second node 242 may be electrically coupled to the drain of the second transistor 224 and the source 233 of the fourth transistor 228. The switch circuit 235 may be electrically coupled between the center pin 238 and a reference voltage (illustrated in FIG. 2 as V_{REF}).

FIG. 2 illustrates the PA 102 as including the upper stack 218, the lower stack 220, the high rail 230, and the low rail 232 as an example configuration. The PA 102 may include any appropriate number of stacks, rails, or combination thereof. For example, the PA 102 may include three stacks, four stacks, or five stacks. In addition, the impedance controller circuit 234 may be electrically coupled between any of the stacks of the rails.

When the transmitter 112 of FIG. 1 is in the on state, the PA 102 may also be in an on state. In contrast, when the transmitter 112 of FIG. 1 is in the off state, the PA 102 may also be in an off state. Operation of the PA 102 in the off state is now discussed.

The impedance controller circuit 234, when the PA 102 is in the off state, may provide the reference voltage to the upper stack 218 and the lower stack 220. The impedance controller circuit 234 providing the reference voltage to the upper stack 218, may cause the upper stack 218 to transition to or maintain the deep shut off state. The impedance controller circuit 234 providing the reference voltage to the lower stack 220 may permit the leakage current to traverse the first transistor 222 and the second transistor 224.

The switch circuit 235 may operate in a closed state when the PA 102 is in the off state. In addition, the switch circuit 235 may operate in an open state when the PA 102 is in the on state. In the closed state, the switch circuit 235 may electrically couple the center tap 238 to the reference voltage. In addition, in the closed state, the switch circuit 235 may provide the reference voltage to the first node 240 and the second node 242 via the inductor 236.

A voltage level of the reference voltage may be greater than a voltage level of the first bias voltage when the PA 102 is in the off state. The voltage level of the first bias voltage, when the PA 102 is in the off state, may be reduced compared to the voltage level of first bias voltage when the PA 102 is in the on state. The voltage level of the reference voltage being greater than the voltage level of the first bias voltage may reduce the difference between the gate voltage and the source voltage of the third transistor 226 and the fourth transistor 228 to be small enough to cause the third transistor 226 and the fourth transistor 228 to enter the deep shut off state (e.g., to become a negative value 0.

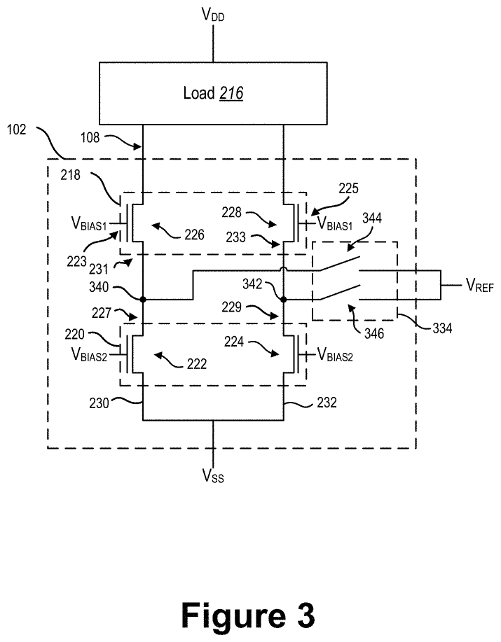

FIG. 3 illustrates another example of the PA 102 that may be implemented in the transceiver system 100 of FIG. 1. electrically coupled to the load 216, in accordance with at least one aspect described in the present disclosure. The PA 102 may include another impedance controller circuit 334.

The impedance controller circuit 334 may include a first switch circuit 344 and a second switch circuit 346. The first switch circuit 344 may be electrically coupled between the reference voltage and a first node 340 (e.g., the high rail 230). The second switch circuit 346 may be electrically coupled between the reference voltage and a second node 342 (e.g., the low rail 232). The first node 340 may be electrically coupled to the source 231 of the third transistor 226 and the drain 227 of the first transistor 222. The second node 342 may be electrically coupled to the source 233 of the fourth transistor 238 and the drain 229 of the second transistor 224.

The first switch circuit 344 may operate in a closed state when the PA 102 is in the off state. In addition, the first switch circuit 344 may operate in an open state when the PA 102 is in the on state. In the closed state, the first switch circuit 344 may electrically couple the first node 340 to the reference voltage. In addition, in the closed state, the first switch circuit 344 may provide the reference voltage to the first node 340 (e.g., the high rail 230).

The second switch circuit 346 may operate in a closed state when the PA 102 is in the off state. In addition, the second switch circuit 346 may operate in an open state when the PA 102 is in the on state. In the closed state, the second switch circuit 346 may electrically couple the second node 342 to the reference voltage. In addition, in the closed state, the second switch circuit 346 may provide the reference voltage to the second node 342 (e.g., the low rail 232).

The impedance controller circuit 334, when the PA 102 is in the off state, may provide the reference voltage to the upper stack 218 and the lower stack 220. The impedance controller circuit 334 providing the reference voltage to the upper stack 218, may cause the upper stack 218 to transition to or maintain the deep shut off state. The impedance controller circuit 334 providing the reference voltage to the lower stack 220 may permit the leakage current to traverse the first transistor 222 and the second transistor 224.

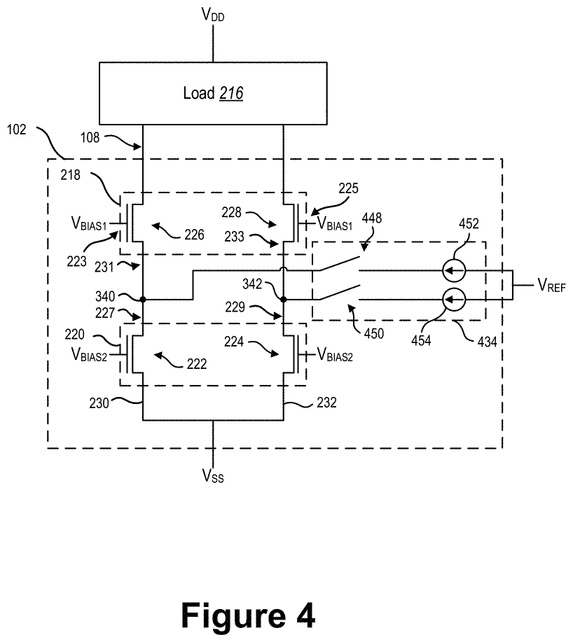

FIG. 4 illustrates yet another example of the PA 102 that may be implemented in the transceiver system 100 of FIG. 1. electrically coupled to the load 216, in accordance with at least one aspect described in the present disclosure. The PA 102 may include yet another impedance controller circuit 434.

The impedance controller circuit 434 may include a first switch circuit 448, a first current source 452, a second switch circuit 450, and a second current source 454. The first switch circuit 448 may be electrically coupled between the first current source 452 and the first node 340 (e.g., the high rail 230). The first current source 452 may also be electrically coupled to the reference voltage. The second switch circuit 450 may be electrically coupled between the second current source 454 and the second node 342 (e.g., the low rail 232). The second current source 454 may also be electrically coupled to the reference voltage.

The first switch circuit 448 may operate in a closed state when the PA 102 is in the off state. In addition, the first switch circuit 448 may operate in an open state when the PA 102 is in the on state. In the closed state, the first switch circuit 448 may electrically couple the first node 340 to the first current source 452. In addition, in the closed state, the first switch circuit 448 may provide the reference voltage to the first node 340 (e.g., the high rail 230) via the first current source 452.

The second switch circuit 450 may operate in a closed state when the PA 102 is in the off state. In addition, the second switch circuit 450 may operate in an open state when the PA 102 is in the on state. In the closed state, the second switch circuit 450 may electrically couple the second node 342 to the second current source 454. In addition, in the closed state, the second switch circuit 450 may provide the reference voltage to the second node 342 (e.g., the low rail 232) via the second current source 454.

The first current source 452, when the PA 102 is in the off state, may control a current level of a leakage current on the high rail 230. The second current source 454, when the PA 102 is in the off state, may control a current level of the leakage current on the low rail 232.

A transceiver may operate in a receive state in which a receiver (e.g., an LNA) receives multiple receive signals via an antenna. The transceiver may also operate in a transmit state in which a transmitter (e.g., a PA) generates transmit signals to be wirelessly transmitted by the antenna. The receiver and the transmitter may be designed as a shared matching network that does not include series transistors (e.g., switches). In addition, the transmitter may include multiple PAs that operate at different times when the transceiver is in the transmit state.

The PA may include a stacked configuration or cascode configuration of the transistors (e.g., an upper stack and a lower stack). The upper stack may be electrically coupled to an output of the PA and the lower stack. The lower stack may be electrically coupled between the upper stack and an electrical ground.

In the receive state, the LNA may receive the receive signals and noise from the PA. The noise may be due to parasitic conductance (e.g., thermal noise, noise due to leakage current, or some combination thereof), an off-impedance level, or some combination thereof of the PA. The noise may degrade operation of the LNA. In addition, in the transmit state, an operating PA within the transmitter may receive the noise from a non-operating PA. The noise may degrade operation of the operating PA.

The parasitic conductance of the PA may occur due to sizing of the transistors, operational parameters of the PA or the transistors, or some combination thereof. For example, a power level of a power supply for the PA may be greater than the power level of the power supply to the other components within the transceiver (e.g., the LNA).

The transistors in the PA may be large enough to push and sink sufficient current to cause the antenna to transmit a wireless signal in a radio frequency (RF). However, a length of gates of the transistors may be relatively short for their size to increase bandwidth or efficiency of the PA or to reduce a footprint of the PA compared to transistors that include long gate lengths. The large transistors, in the off state, may generate greater leakage current, greater shunt conductance, or some combination thereof compared to small transistors. The large transistors with short gate lengths, in the off state, may generate even greater leakage current, even greater shunt conductance, or some combination thereof compared to small transistors.

An off-biasing voltage range of large transistors that include short gate lengths (e.g., a voltage range to achieve off state biasing) may be narrower than the off-biasing voltage range of large transistors that include long gate lengths. The off-biasing voltage range of the large transistors that include short gate lengths may be difficult to achieve in the off state, which may prevent the transistors from entering a deep shut off state. The deep shut off state may include when a difference between a gate voltage and a source voltage is smaller than a threshold voltage of the transistor (e.g., a minimum difference between the gate voltage and the source voltage to conduct current on the transistor). For example, the deep shut off state may include when the difference between the gate voltage and the source voltage is equal to a negative value (e.g., when a voltage level of the gate voltage is less than a voltage level of the source voltage). In addition, process variations during wafer production may further narrow or alter the off-biasing voltage range. The process variations may cause the off-biasing voltage range vary between transistors, wafers, and PAs. In addition, a hot corner in the PA (e.g., a portion of the PA that operates in a hot environment or lower voltage threshold corner) may reduce or narrow the off-biasing voltage range even more. When the transistors of the upper stack fail to enter the deep shut off state, an off-impedance level of the PA may be reduced, which may contribute to the noise.

Some PAs include an impedance controller configured to reduce the impact of the noise. Some impedance controller technologies may include a tail switch electrically coupled between the lower stack and the electrical ground. The tail switch, when the PA is in the off state, may electrically isolate the lower stack from the electrical ground to prevent the leakage current from flowing between the power supply and the electrical ground (e.g., switch off a leakage path between the lower stack and the electrical ground). The tail switch may electrically isolate the lower stack from the electrical ground to prevent the leakage current from flowing to also increase the impedance of the upper stack. These impedance controller technologies may create a voltage drop within the PA due to a differential configuration of the PA. The voltage drop of the tail switch may reduce efficiency, gain, linearity, or some combination thereof of the PA. In addition, to reduce the voltage drop of the tail switch, the tail switch may be large, which may increase a footprint and parasitic conductance of the PA.

Some PAs may be designed to increase the threshold voltages of the transistors in the PA to reduce the noise. However, these PAs may include reduced performance. For example, these PAs may include a reduced gain, reduced speed, increased noise, or some combination thereof.

The impedance controller circuit may provide a reference voltage to the sources of the upper stack and the drains of the lower stack. In the off state of the PA, the impedance controller circuit may provide the reference voltage to drive the upper stack into the deep cut off state. In addition, the leakage current of the lower stack may be routed to flow between the reference voltage and the electrical ground.

The PA may operate in the on state and the off state. The PA may include transistors that are electrically coupled to the electrical ground and the output of the PA. The transistors may be arranged in a stacked configuration or a cascode configuration. The transistors may include an upper stack and a lower stack. The upper stack may be electrically coupled to the output of the PA. The lower stack may be electrically coupled between the upper stack and the electrical ground. The lower stack may include a first transistor and a second transistor. The upper stack may include a third transistor and a fourth transistor. The third transistor and the fourth transistor may each include a gate electrically coupled to a first bias voltage. The transistors may be arranged in a multiple stack configuration. For example, the transistors may be arranged in a three stack, a four stack, or an N^{th} stack configuration.

The PA may include an impedance controller circuit. The impedance controller circuit may be electrically coupled to the transistors and a reference voltage. The impedance controller circuit may be electrically coupled between any drain-source connection of the transistors. For example, the drain source connection of a fifth transistor and a seventh transistor. The impedance controller may provide the reference voltage to the transistors when the PA is in the off state. The impedance controller circuit may provide the reference voltage to cause a portion of the transistors to transition to the deep shut off state. For example, the impedance controller circuit may provide the reference voltage to cause the upper stack to transition to the deep shut off state.

The deep shut off state may prevent sub-threshold voltage conduction by the upper stack to prevent the leakage current from traversing the upper stack. The deep shut off state may include a state in which current flow between the source and the drain of a transistor is very small (e.g., the difference between the gate voltage and the source voltage is much lower than the voltage threshold). For example, the deep shut off state may include when the difference between the gate voltage and the source voltage is equal to a negative value (e.g., when a voltage level of the gate voltage is less than a voltage level of the source voltage).

A voltage level of the reference voltage may be greater than a voltage level of the first bias voltage when the PA is in the off state. For example, the voltage level of the reference voltage may be greater than the voltage level of the first bias voltage at the gates of the third transistor and the fourth transistor, when the PA is in the off state. The reference voltage being greater than the voltage level of the first bias voltage may cause the third transistor and the fourth transistor to operate in the deep shut off state. The voltage level of the first bias voltage may be reduced when the PA is in the off state compared to when the PA is in the on state.

The impedance controller circuit may be electrically coupled to the upper stack and the lower stack. The impedance controller circuit may electrically bypass the upper stack to cause the leakage current to traverse the lower stack and flow between the reference voltage and the electrical ground. The impedance controller circuit may cause the upper stack to enter the deep shut off state to prevent the leakage current from traversing the upper stack.

The impedance controller circuit may include an inductor and a switch circuit. The impedance controller may include a first node electrically coupled to the drain of the first transistor and a source of the third transistor. The impedance controller may also include a second node electrically coupled to the drain of the second transistor and the source of the fourth transistor. The inductor may include a center tap. The switch circuit may be electrically coupled between the reference voltage and the center tap.

The switch circuit may operate in a closed state when the PA is in the off state to electrically couple the center tap to the reference voltage. In addition, the switch circuit may operate in the closed state when the PA is in the off state to provide the reference voltage to the source of the fourth transistor, the source of the third transistor, the drain of the first transistor, and the drain of the second transistor.

The transistors may form differential rails that include a high rail and a low rail. The high rail may include the first transistor and the third transistor. The low rail may include the second transistor and the fourth transistor. The high rail may include a positive voltage rail and the low rail may include a negative voltage rail. Alternatively, the high rail may include a higher voltage relative to the low rail.

The first node of the inductor may be electrically coupled to the high rail. The second node of the inductor may be electrically coupled to the low rail. The switch circuit may operate in the closed state when the PA is in the off state to provide the reference voltage to the high rail and the low rail.

The impedance controller circuit may force the voltage on the high rail and the low rail to be equivalent to the reference voltage. In addition, the impedance controller may direct leakage current due to the lower stack, the upper stack, the antenna, the output of the PA, or some combination thereof to flow on a newly introduced path.

The PA may include transistors electrically coupled to an electrical ground and an output of the PA. The transistors may for differential rails that include a high rail and a low rail. The high rail may include a first transistor and a third transistor. The low rail may include a second transistor and a fourth transistor. The PA may include an impedance controller circuit electrically coupled to the high rail, the low rail, and a reference voltage. The impedance controller circuit may provide the reference voltage to the high rail and the low rail when the PA is in the off state to cause a portion of the transistors to transition to a deep shut off state. The deep shut off state may prevent sub-threshold voltage conduction by the third transistor and the fourth transistor to prevent a leakage current from traversing the third transistor and the fourth transistor.

The impedance controller circuit may include two separate switches to bias a first node and a second node (e.g., a middle point) of the high rail and the low rail to the reference voltage. The switches may be small in size and may add very little parasitic conduction compared to a tail switch.

The impedance controller circuit may include a first switch electrically coupled between the voltage reference and the high rail. The first switch may be electrically coupled to a drain of the first transistor and a source of the third transistor. The first switch may operate in a closed state when the PA is in the off state to electrically couple the high rail to the reference voltage.

The impedance controller circuit may include a second switch electrically coupled between the voltage reference and the low rail. The second switch may be electrically coupled to a drain of the second transistor and a source of a fourth transistor. The second switch may operate in a closed state when the PA is in the off state to electrically couple the low rail to the reference voltage.

The voltage level of the reference voltage, when the PA is in the off state, may be greater than a voltage level of a gate of the third transistor and a gate of the fourth transistor to cause the third transistor and the fourth transistor to operate in the deep shut off state.

The transistors may be arranged in a stacked configuration. The transistors may include an upper stack and a lower stack. The impedance controller circuit may be electrically coupled to the upper stack and the lower stack. The upper stack may be electrically coupled to the output of the PA. The upper stack may include gates and each gate of the upper stack may be electrically coupled to a voltage. The lower stack may be electrically coupled between the upper stack and the electrical ground.

The impedance controller circuit may electrically bypass the upper stack to cause the leakage current to traverse the lower stack and flow between the reference voltage and the electrical ground. The impedance controller circuit may also cause the upper stack to operate in the deep shut off state to prevent the leakage current from traversing the upper stack.

The impedance controller circuit may include a current source to accurately control a current level of the leakage current. Part or all of the leakage current from the lower stack may be routed between the reference voltage and the electrical ground.

The impedance controller circuit may include a first current source, a second current source, a first switch circuit, and a second switch circuit. The first current source may be electrically coupled to the voltage reference. The second current source may be electrically coupled to the voltage reference. The first switch circuit may be electrically coupled between the first current source and the high rail. The second switch circuit may be electrically coupled between the second current source and the low rail.

The first switch circuit may operate in a closed state when the PA is in the off state to electrically couple the high rail to the first current source. The first current source may control a current level of a leakage current on the high rail. The second switch circuit may operate in a closed state when the PA is in the off state to electrically couple the low rail to the second current source. The second current source may control a current level of the leakage current on the low rail.

A transceiver system may operate in a receive state and a transmit state. The transceiver system may include an antenna, an LNA, and a PA. The LNA may be electrically coupled to the antenna. The PA may include an output electrically coupled to the antenna and the LNA. The PA may also include transistors electrically coupled to the output. The transistors may provide an output voltage to the antenna when the transceiver system is in the transmit state. The transistors may be arranged in a stacked configuration. The transistors may include an upper stack electrically coupled to the antenna and the LNA. The transistors may also include a lower stack electrically coupled between the upper stack and an electrical ground.

The PA may also include an impedance controller circuit electrically coupled to the transistors and a reference voltage. The impedance controller circuit may be electrically coupled to the upper stack and the lower stack. The impedance controller circuit may provide the reference voltage to the transistors when the transceiver system is in the receive state to cause a portion of the transistors to transition to the deep shut off state.

The impedance controller circuit may electrically bypass the upper stack to cause the leakage current to traverse the lower stack and flow between the reference voltage and the electrical ground. The impedance controller circuit may also cause the upper stack to operate in the deep shut off state to prevent the leakage current from traversing the upper stack.

The transistors may form differential rails that include a high rail and a low rail. The impedance controller circuit may include an inductor and a switch circuit. The inductor may include a first node electrically coupled to the high rail. The inductor may also include a second node electrically coupled to the low rail. In addition, the inductor may include a center tap. The switch circuit may be electrically coupled between the center tap and the reference voltage. The switch circuit may operate in a closed state when the transceiver system is in the receive state to electrically couple the center tap to the reference voltage and provide the reference voltage to the high rail and the low rail.

The impedance controller circuit may include a first switch electrically coupled between the voltage reference and the high rail. The impedance controller circuit may also include a second switch circuit electrically coupled between the voltage reference and the low rail. The first switch may operate in a closed state when the transceiver system is in the receive state to electrically couple the high rail to the reference voltage. The second switch may operate in a closed state when the transceiver system is in the receive state to electrically couple the low rail to the reference voltage.

The impedance controller circuit may include a first current source electrically coupled to the voltage reference. The impedance controller circuit may also include a second current source electrically coupled to the voltage reference. In addition, the impedance controller circuit may include a first switch circuit electrically coupled between the first current source and the high rail. Further, the impedance controller circuit may include a second switch circuit electrically coupled between the second current source and the low rail. The first switch may operate in a closed state when the transceiver system is in the receive state to electrically couple the high rail to the first current source. The first current source may control a current level of a leakage current on the high rail. The second switch may operate in a closed state when the transceiver system is in the receive state to electrically couple the low rail to the second current source. The second current source may control a current level of the leakage current on the low rail.

The impedance controller circuit may increase the off impedance of the upper stack, reduce the noise, or some combination thereof in the off state of the PA. In addition, the impedance controller circuit may cause the leakage current to flow between the reference voltage and the electrical ground rather than between the power supply and the electrical ground. Further, the impedance controller circuit may not degrade performance of the PA because the impedance controller circuit does not alter the upper stack or the lower stack (e.g., the impedance controller does not alter differential rails of the transistors). Likewise, the impedance controller circuit may reduce a fabrication cost or manufacturing cost of the PA compared to PAs that include the tail switch.

The impedance controller circuit causing the upper stack to enter the deep shut off state may also compensate for process variations that occur. For example, the voltage threshold of the upper stack may be inconsistent and the impedance controller circuit providing the reference voltage may increase the off impedance even more than standard operation.

The impedance controller circuit may apply known voltages on both the gates and the sources of the upper stack to maximally turn off the PA to limit current flow without device breakdown or reliability concerns of the PA.

The impedance controller circuit that includes the inductor may not add any parasitic components to the circuit in a differential PA, because the inductor may already be implemented.

In a simulation, a stacked PA was placed together with an LNA model and an antenna port (e.g., a transceiver system). The LNA included a four-decibel noise figure. A middle point of the stacked PA (e.g., the first node and the second node) were connected to a voltage source via the center tap of a differential inductor and a switch. During the simulation, the transceiver system was configured to a receive state. The switch closed and the voltage source forced the upper stack of the PA to enter the deep shut off state.

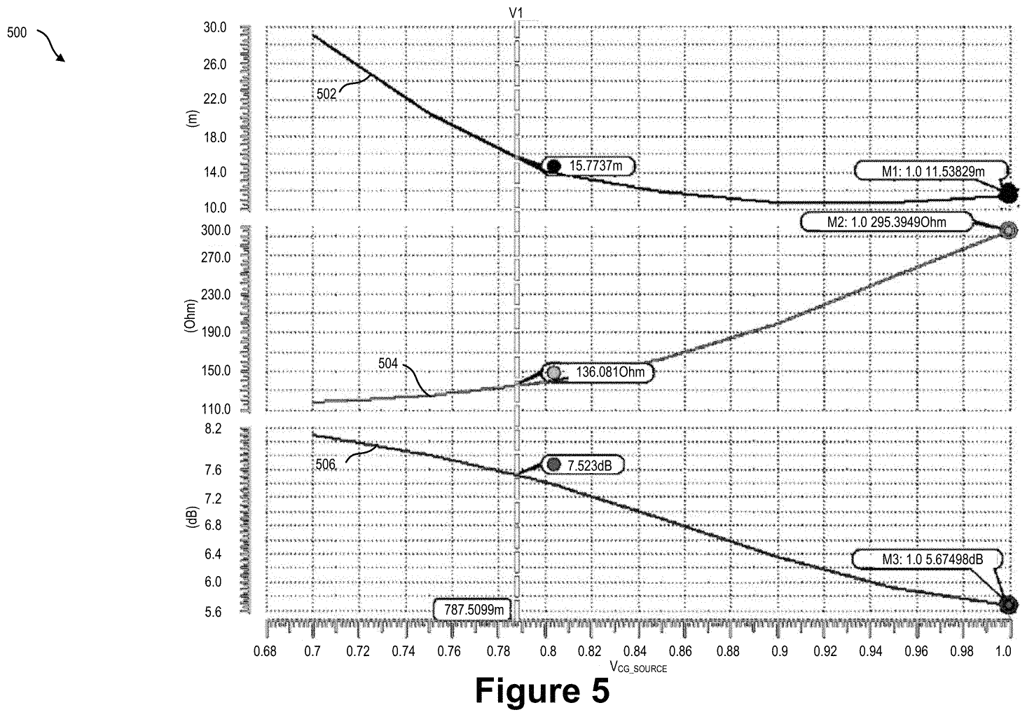

FIG. 5 illustrates a graphical representation 500 of simulations using a circuit design of the PA 102 of FIG. 2, in accordance with at least one aspect described in the present disclosure. During the simulation, voltage sweep was performed including the switch in the open state (e.g., no impedance controller operation) and the closed state (e.g., impedance controller operation as described in the present disclosure. During the voltage sweep, a leakage power of the PA with the switch in the open state was measured as 15.44 milliwatts, which was reduced to 11.54 milliwatts when the switch was in closed state. Curve 502 represents the measured leakage power during the voltage sweep. In addition, a real part of the off impedance of the PA with the switch in the open state was measured as one hundred thirty-eight ohms, which was reduced to two hundred ninety-five ohms when the switch was in the closed state. Curve 504 represents the measured off impedance during the voltage sweep. In addition, a receive noise figure with the switch in the open state was measured as 7.52 decibels, which was reduced to 5.67 decibels when the switch was in the closed state. Curve 506 represents the measured receive noise figure during the voltage sweep.

While the above descriptions and connected figures may depict electronic device components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. A power amplifier configured to operate in an on state and an off state, the power amplifier comprising:
a plurality of transistors electrically coupled to an electrical ground and an output of the power amplifier; and
an impedance controller circuit:
electrically coupled to the plurality of transistors and a reference voltage; and
configured to provide the reference voltage to the plurality of transistors when the power amplifier is in the off state to cause a portion of the plurality of transistors to transition to a deep shut off state.

2. The power amplifier of claim 1, wherein the plurality of transistors are arranged in a stacked configuration and the plurality of transistors comprise:
an upper stack electrically coupled to the output of the power amplifier; and
a lower stack electrically coupled between the upper stack and the electrical ground, wherein the impedance controller circuit is electrically coupled to the upper stack and the lower stack, the impedance controller circuit is configured to:
electrically bypass the upper stack to cause a leakage current to traverse the lower stack and flow between the reference voltage and the electrical ground; and
cause the upper stack to operate in the deep shut off state to prevent the leakage current from traversing the upper stack.

3. The power amplifier of claim 2, wherein the upper stack comprises a plurality of gates and each gate of the plurality of gates is electrically coupled to a bias voltage and a voltage level of the reference voltage is greater than a voltage level of the bias voltage when the power amplifier is in the off state.

4. The power amplifier of claim 1, wherein the plurality of transistors form differential rails comprising a high rail and a low rail and the impedance controller circuit comprises:
an inductor comprising:
a first node electrically coupled to the high rail;
a second node electrically coupled to the low rail; and
a center tap; and
a switch circuit electrically coupled between the center tap and the reference voltage, wherein the switch circuit is configured to operate in a closed state when the power amplifier is in the off state to electrically couple the center tap to the reference voltage and provide the reference voltage to the high rail and the low rail.

5. The power amplifier of claim 4, wherein the high rail comprises a first transistor and the low rail comprises a second transistor and wherein the first node is electrically coupled to a drain of the first transistor and the second node is electrically coupled to a drain of the second transistor.

6. The power amplifier of claim 4, wherein the high rail comprises a third transistor and the low rail comprises a fourth transistor, and wherein:
the first node is electrically coupled to a source of the third transistor;
the second node is electrically coupled to a source of the fourth transistor; and
a voltage level of the reference voltage, when the power amplifier is in the off state, is greater than a voltage level of a gate of the third transistor and a gate of the fourth transistor to cause the third transistor and the fourth transistor to operate in the deep shut off state.

7. The power amplifier of claim 6, wherein the deep shut off state prevents sub-threshold voltage conduction by the third transistor and the fourth transistor to prevent a leakage current from traversing the third transistor and the fourth transistor.

8. A power amplifier configured to operate in an on state and an off state, the power amplifier comprising:
a plurality of transistors that form differential rails comprising a high rail and a low rail, and the plurality of transistors are electrically coupled to an electrical ground and an output of the power amplifier; and
an impedance controller circuit:
electrically coupled to the high rail, the low rail, and a reference voltage; and
configured to provide the reference voltage to the high rail and the low rail when the power amplifier is in the off state to cause a portion of the plurality of transistors to transition to a deep shut off state.

9. The power amplifier of claim 8, wherein the plurality of transistors are arranged in a stacked configuration and comprise:
an upper stack electrically coupled to the output of the power amplifier; and
a lower stack electrically coupled between the upper stack and the electrical ground, wherein the impedance controller circuit is electrically coupled to the upper stack and the lower stack, the impedance controller circuit is configured to:
electrically bypass the upper stack to cause a leakage current to traverse the lower stack and flow between the reference voltage and the electrical ground; and
cause the upper stack to operate in the deep shut off state to prevent the leakage current from traversing the upper stack.

10. The power amplifier of claim 9, wherein the upper stack comprises a plurality of gates and each gate of the plurality of gates is electrically coupled to a bias voltage and a voltage level of the reference voltage is greater than a voltage level of the bias voltage when the power amplifier is in the off state.

11. The power amplifier of claim 8, wherein the impedance controller circuit comprises:
a first switch circuit:
electrically coupled between the voltage reference and the high rail; and
configured to operate in a closed state when the power amplifier is in the off state to electrically couple the high rail to the reference voltage; and
a second switch circuit:
electrically coupled between the voltage reference and the low rail; and
configured to operate in a closed state when the power amplifier is in the off state to electrically couple the low rail to the reference voltage.

12. The power amplifier of claim 11, wherein the high rail comprises a first transistor and the low rail comprises a second transistor and wherein the first switch circuit is electrically coupled to a drain of the first transistor and the second switch circuit is electrically coupled to a drain of the second transistor.

13. The power amplifier of claim 11, wherein the high rail comprises a third transistor and the low rail comprises a fourth transistor and wherein:
the first switch circuit is electrically coupled to a source of the third transistor;
the second switch circuit is electrically coupled to a source of a fourth transistor; and
a voltage level of the reference voltage, when the power amplifier is in the off state, is greater than a voltage level of a gate of the third transistor and a gate of the fourth transistor to cause the third transistor and the fourth transistor to operate in the deep shut off state.

14. The power amplifier of claim 13, wherein the deep shut off state prevents sub-threshold voltage conduction by the third transistor and the fourth transistor to prevent a leakage current from traversing the third transistor and the fourth transistor.

15. The power amplifier of claim 8, wherein the impedance controller circuit comprises:
a first current source electrically coupled to the voltage reference;
a second current source electrically coupled to the voltage reference;
a first switch circuit electrically coupled between the first current source and the high rail, the first switch circuit configured to operate in a closed state when the power amplifier is in the off state to electrically couple the high rail to the first current source, wherein the first current source controls a current level of a leakage current on the high rail; and
a second switch circuit electrically coupled between the second current source and the low rail, the second switch circuit configured to operate in a closed state when the power amplifier is in the off state to electrically couple the low rail to the second current source, wherein the second current source controls a current level of the leakage current on the low rail.

16. A transceiver system configured to operate in a receive state and a transmit state, the transceiver system comprising:
an antenna;
a low noise amplifier electrically coupled to the antenna; and
a power amplifier comprising:
an output electrically coupled to the antenna and the low noise amplifier;
a plurality of transistors electrically coupled to the output and configured to provide an output voltage to the antenna when the transceiver system is in the transmit state; and
an impedance controller circuit:
electrically coupled to the plurality of transistors and a reference voltage; and
configured to provide the reference voltage to the plurality of transistors when the transceiver system is in the receive state to cause a portion of the plurality of transistors to transition to a deep shut off state.

17. The transceiver system of claim 16, wherein the plurality of transistors are arranged in a stacked configuration and the plurality of transistors comprise:
an upper stack electrically coupled to the antenna and the low noise amplifier; and
a lower stack electrically coupled between the upper stack and an electrical ground, wherein the impedance controller circuit is electrically coupled to the upper stack and the lower stack, the impedance controller circuit is configured to:
electrically bypass the upper stack to cause a leakage current to traverse the lower stack and flow between the reference voltage and the electrical ground; and
cause the upper stack to operate in the deep shut off state to prevent the leakage current from traversing the upper stack.

18. The transceiver system of claim 16, wherein the plurality of transistors form differential rails comprising a high rail and a low rail and the impedance controller circuit comprises:
an inductor comprising:
a first node electrically coupled to the high rail;
a second node electrically coupled to the low rail; and
a center tap; and
a switch circuit electrically coupled between the center tap and the reference voltage, wherein the switch circuit is configured to operate in a closed state when the transceiver system is in the receive state to electrically couple the center tap to the reference voltage and provide the reference voltage to the high rail and the low rail.

19. The transceiver system of claim 16, wherein the impedance controller circuit comprises:
a first switch circuit:
electrically coupled between the voltage reference and the high rail; and
configured to operate in a closed state when the transceiver system is in the receive state to electrically couple the high rail to the reference voltage; and
a second switch circuit:
electrically coupled between the voltage reference and the low rail; and
configured to operate in a closed state when the transceiver system is in the receive state to electrically couple the low rail to the reference voltage.

20. The transceiver system of claim 16, wherein the impedance controller circuit comprises:
a first current source electrically coupled to the voltage reference;
a second current source electrically coupled to the voltage reference;
a first switch circuit electrically coupled between the first current source and the high rail, the first switch circuit configured to operate in a closed state when the transceiver system is in the receive state to electrically couple the high rail to the first current source, wherein the first current source controls a current level of a leakage current on the high rail; and
a second switch circuit electrically coupled between the second current source and the low rail, the second switch circuit configured to operate in a closed state when the transceiver system is in the receive state to electrically couple the low rail to the second current source, wherein the second current source controls a current level of the leakage current on the low rail.
